(19) United States
(12) Patent Application Publication
(10) Pub. No.: US 2024/0421564 A1
(43) Pub. Date: Dec. 19, 2024

(54) High frequency wavelength sweeping laser for imitating continuous emission with tunable intensity profile

(71) Applicant: SIGNIFY HOLDING B.V., EINDHOVEN (NL)

(72) Inventors: RIFAT ATA MUSTAFA HIKMET, EINDHOVEN (NL); TIES VAN BOMMEL, HORST (NL)

(21) Appl. No.: 18/708,481

(22) PCT Filed: Nov. 4, 2022
(86) PCT No.: PCT/EP2022/080788

§ 371 Date: May 8, 2024

(30) Foreign Application Priority Data
Nov. 9, 2021 (EP) 21207054.4

(51) Int. Cl. H01S 5/42; F21K 9/64; F21V 9/30; F21Y 113/10; F21Y 115/30; H01S 5/183

(52) U.S. Cl. CPC H01S 5/423; F21K 9/64; F21V 9/30; H01S 5/183; F21Y 2113/10; F21Y 2115/30

(57) ABSTRACT

The invention provides a light generating system (1000) comprising n first vertical cavity surface emitting lasers (110) and a control system (300), wherein n≥1, wherein each of the n first vertical cavity surface emitting lasers (110) is configured to generate first laser light (111) changing between at least two centroid wavelengths (λ_{nc,1}, λ_{nc,2}) having a wavelength difference of at least 10 nm, with a changing frequency of at least 50 Hz; wherein the control system (300) is configured to control the n first vertical cavity surface emitting lasers (110) such that system light (1001) is generated comprising the first laser light (111) of at least one of the n first vertical cavity surface emitting lasers (110), and wherein the control system (300) is configured to control a spectral power distribution of the system light (1001), wherein the system light (1001) is white light having a correlated color temperature in a range from 1800 K to 8000 K and a color rendering index of at least 70.

### FIELD OF THE INVENTION

The invention relates to a light generating system. The invention further relates to a light generating device comprising such light generating system.

### BACKGROUND OF THE INVENTION

Devices comprising vertical cavity lasers are known in the art. For instance, WO2004/107512 describes a white-light laser integrated structure comprising: a) a substrate and b) one or more individually addressable laser light pixels formed on the substrate for emitting a white beam of laser light perpendicular to the substrate, each of the one or more individually addressable laser light pixels include one or more organic light emitting diodes (OLEDs) and a plurality of organic vertical cavity lasers that are arranged to be optically pumped by the one or more OLEDs, wherein the plurality of organic vertical cavity lasers emit differently colored light and the one or more individually addressable laser light emitting pixels emit substantially white light when the differently colored light is combined. The plurality of organic vertical cavity lasers emits two different colors of light.

### SUMMARY OF THE INVENTION

While white LED sources can give an intensity of e.g. up to about 300 lm/mm²; static phosphor converted laser white sources can give an intensity even up to about 20.000 lm/mm². Ce doped garnets (e.g. YAG, LuAG) may be the most suitable luminescent convertors which can be used for pumping with blue laser light as the garnet matrix has a very high chemical stability. Further, at low Ce concentrations (e.g. below 0.5%) temperature quenching may only occur above about 200° C. Furthermore, emission from Ce has a very fast decay time so that optical saturation can essentially be avoided. Assuming e.g. a reflective mode operation, blue laser light may be incident on a phosphor. This may in embodiments realize almost full conversion of blue light, leading to emission of converted light. It is for this reason that the use of garnet phosphors with relatively high stability and thermal conductivity is suggested. However, also other phosphors may be applied. Heat management may remain an issue when extremely high-power densities are used.

High brightness light sources can be used in applications such as projection, stage-lighting, spot-lighting and automotive lighting. For this purpose, laser-phosphor technology can be used wherein a laser provides laser light and e.g. a (remote) phosphor converts laser light into converted light. The phosphor may in embodiments be arranged on or inserted in a heatsink for improved thermal management and thus higher brightness.

It appears desirable to provide light sources that are wavelength tunable. In general, laser-based light sources, however, are not wavelength tunable. Further, it appears desirable to provide lighting devices having a spectral power distribution substantially conformal with the black body locus (at a desired correlated color temperature CCT).

Hence, it is an aspect of the invention to provide an alternative light generating system, which preferably further at least partly obviates one or more of above-described drawbacks. The present invention may have as object to overcome or ameliorate at least one of the disadvantages of the prior art, or to provide a useful alternative.

In a first aspect, the invention provides a light generating system (“system”) comprising n first vertical cavity surface emitting lasers, a second light generating device and a control system, wherein n≥1. The second light generating device is configured to generate second light generating device light. Each of the n first vertical cavity surface emitting lasers is configured to generate ((in a first operational mode of the light generating system) first laser light changing between at least two centroid wavelengths (λ_{nc,1}, λ_{nc,2}), wherein the at least two centroid wavelengths may have a wavelength difference of at least 10 nm. Further, the first laser light is changed between at least two centroid wavelengths (λ_{nc,1}, λ_{nc,2}) with a changing frequency of at least 50 Hz. The control system is configured to control the n first vertical cavity surface emitting lasers such that (in the first operational mode) of the light generating system) system light is generated comprising the first laser light of at least one of the n first vertical cavity surface emitting lasers and the second light generating device light. Further, the control system is configured to control a spectral power distribution of the system light. Especially, (in the first operational mode) the system light is white light having a correlated color temperature in a range from 1800 K to 8000 K and a color rendering index of at least 70. Therefore, especially the invention provides a light generating system comprising n first vertical cavity surface emitting lasers and a control system, wherein n≥1, wherein each of the n first vertical cavity surface emitting lasers is configured to generate ((in a first operational mode of the light generating system) first laser light changing between at least two centroid wavelengths (λ_{nc,1}, λ_{nc,2}) having a wavelength difference of at least 10 nm, with a changing frequency of at least 50 Hz; wherein the control system is configured to control the n first vertical cavity surface emitting lasers such that (in the first operational mode) of the light generating system) system light is generated comprising the first laser light of at least one of the n first vertical cavity surface emitting lasers, and wherein especially the control system is configured to control a spectral power distribution of the system light, wherein (in the first operational mode), the system light is white light having a correlated color temperature in a range from 1800 K to 8000 K and a color rendering index of at least 70.

With such system, it is possible to provide light having a controllable spectral power distribution. Further, with such system it may be possible to provide light having a controllable correlated color temperature and/or a controllable color rendering index. Yet, with such system it may be possible to provide a spectral power distribution partially or substantially conformal to the spectral power distribution (in the visible) of a black body radiator (emission).

As indicated above, the light generating system comprises n first vertical cavity surface emitting lasers.

A vertical-cavity surface-emitting laser, or VCSEL, is known in the art and may especially be a type of semiconductor laser diode with laser beam emission perpendicular from the top surface, contrary to edge-emitting semiconductor lasers (also in-plane lasers) which emit from surfaces formed by cleaving the individual chip out of a wafer. VCSELs may be tunable in emission wavelength, as known in the art. For instance, Dupont et al., Applied Physics Letters 98(16):161105-161105-3, DOI:10.1063/1.3569591, or Wendi Chang et al., Applied Physics Letters 105(7):073303, DOI:10.1063/1.4893758, or Thor Ansbaek, IEEE Journal of Selected Topics in Quantum Electronics 19(4):1702306-1702306, DOI:10.1109/JSTQE.2013.2257164, or C. J. Chang-Hasnain, IEEE Journal of Selected Topics in Quantum Electronics (Volume: 6, Issue: 6, November-December 2000), DOI: 10.1109/2944.902146, or Kögel et al., IEEE Sensors Journal, December 2007, volume 7, no. 11, pages 1483-1489, or Jayaraman, et al., Electron Lett. 2012 Jul. 5; 48(14): 867-869. doi: 10.1049/el.2012.1552, all document herein incorporated by reference, describe emission wavelength tunable VCSELs. Especially, with varying electrical voltage, the spectral power distribution of the VCSEL may vary. Hence, the term “VCSEL” may thus especially refer herein to a tunable VCSEL, as known in the art. Such tunable VCSELs may be based on MEMS technology. Such (tunable) VCSEL may also be indicated as “MEMS VCSEL”. Therefore, in embodiments the laser diode may comprise a vertical-cavity surface-emitting laser (VCSEL) that has single-mode light emission and a long coherence length. The wavelength sweep may be implemented using a micro-electro-mechanical system (MEMS) to change the length of the laser cavity by which a stable and rapid wavelength sweep results.

Hence, with a VCSEL different spectral power distributions may be generated. Especially, the VCSEL is configured to generate (during operation of the VCSEL) first laser light. Therefore, the first laser light may have a controllable spectral power distribution. By controlling the spectral power distribution of the first VCSEL(s) the spectral power distribution of the system light may be controlled. To control the spectral power distribution, a control system may be applied. Hence, the light generating system may also comprise a control system.

The first vertical cavity surface emitting laser may provide first laser light having at least two different spectral power distributions at different moments in time, respectively. Hence, especially the first vertical cavity surface emitting laser is operated in a mode wherein during different time periods light may be produced with different spectral power distributions. In other words, as the spectral power distribution of the VCSEL may be controllable, the time dependent centroid wavelength may vary over time. As this may occur relatively fast, a fixed spectral power distribution may be perceived by the eye, and thus effectively an (fixed) time averaged centroid wavelength may be perceived. Of course, when changing the spectral power distribution from a first spectral power distribution to a second spectral power distribution in a time period that the change can be followed with the eye, the time averaged centroid wavelength will also change from a first value to a second value.

In embodiments of an operational mode of the system, the change between the at least two different spectral power distributions may be faster than the human eye can perceive. Hence, the change between the at least two different spectral power distributions may be within 0.025 seconds, such as within 0.02 seconds, like even within about 0.0167 seconds. With such fast changes, the eye will not see changes, but will perceive an essentially fixed spectral power distribution having a time averaged centroid wavelength. Hence, the term “time averaged centroid wavelength” may herein especially refer to centroid wavelengths of the first laser light (of a VCSEL) averaged over a time period longer than about 0.0167 seconds, more especially longer than 0.02 seconds. Hence, whereas centroid wavelengths may change within periods within 0.02 seconds, such as in periods within 0.0167 seconds, the human eye may perceive a time averaged centroid wavelength that may be essentially fixed over time (during the first operational mode).

The first vertical cavity surface emitting laser may in embodiments change, such as sweep, between (at least) two spectral power distributions, one having a first centroid wavelength λ_{nc,1}, and one having a second centroid wavelength λ_{nc,2}. Instead of the term “sweep”, and similar terms, also the term “scan”, or similar terms, may be used.

A spectral power distribution may be characterized by a centroid wavelength. The term “centroid wavelength”, also indicated as λc, is known in the art, and refers to the wavelength value where half of the light energy is at shorter and half the energy is at longer wavelengths; the value is stated in nanometers (nm). It is the wavelength that divides the integral of a spectral power distribution into two equal parts as expressed by the formula λc=Σλ*I(λ)/(ΣI(λ), where the summation is over the wavelength range of interest, and I(λ) is the spectral energy density (i.e. the integration of the product of the wavelength and the intensity over the emission band normalized to the integrated intensity). The centroid wavelength may e.g. be determined at operation conditions.

Hence, especially the first vertical cavity surface emitting laser may comprise a wavelength variable light generating device configured to generate in an operational mode of the light generating system first laser light changing between at least two centroid wavelengths (λ_{n,1}, λ_{nc,2}). Hence, effectively in an operational mode the first vertical cavity surface emitting laser (or more precisely its device light) may sweep between two centroid wavelengths. When changing from a first centroid wavelength and a second centroid wavelength, there may be intermediate centroid wavelengths. Therefore, the term “at least two centroid wavelengths (λ_{nc,1}, λ_{nc,2})” is used. The at least two centroid wavelengths (λ_{nc,1}, λ_{nc,2}) may in embodiments also be indicated as outer centroid wavelengths. The first and second centroid wavelengths (λ_{n,1}, λ_{nc,2}) may have a difference of at least 10 nm, such as at least 20 nm, like at least 30 nm, or even in embodiments at least 40 nm (like even at least 60 nm, or even at least 80 nm, such as in specific embodiments at least 100 nm). In specific embodiments, a difference between the at least two centroid wavelengths (λ_{nc,1}, λ_{nc,2}) may be at least 50 nm. Further, the change from the first centroid wavelength to the second centroid wavelength may be with a frequency of at least 40 Hz, like at least 50 Hz, or more especially at least 60 Hz, like at least 80 Hz (and in specific embodiments (even) at least 100 Hz). Hence, in embodiments the first vertical cavity surface emitting laser comprises a wavelength variable light generating device configured to generate in an operational mode of the light generating system first laser light changing between at least two centroid wavelengths (λ_{nc,1}, λ_{nc,2}) having a wavelength difference of at least 10 nm, with a changing frequency of at least 40 Hz. Especially, the changing frequency may be at least 60 Hz.

The change between the (at least two) centroid wavelengths (λ_{nc,1}, λ_{nc,2}) may in embodiments be a jumping change, wherein in a first time period first laser light having the first centroid wavelength is provided, and wherein in a second time period first laser light having the second centroid wavelength is provided, and wherein between the first time period and the second time period there is essentially no first laser light having a centroid wavelength different from the (at least two) centroid wavelengths (λ_{nc,1}, λ_{nc,2}). In alternative embodiments, however, the change between the (at least two) centroid wavelengths (λ_{nc,1}, λ_{nc,2}) may in embodiments be a sweeping change, wherein in a first time period first laser light having the first centroid wavelength is provided, and wherein in a second time period first laser light having the second centroid wavelength is provided, and wherein between the first time period and the second time period there first laser light having a centroid wavelength different from the (at least two) centroid wavelengths (λ_{nc,1}, λ_{nc,2}) is provided. This may lead to first laser light having a centroid wavelength changing over time between the (at least two) centroid wavelengths (λ_{nc,1}, λ_{nc,2}). Especially, in embodiments may lead to first laser light having a centroid wavelength continuously changing over time (at least two) centroid wavelengths (λ_{nc,1}, λ_{nc,2}). Essentially, this may imply a continuous change during which first laser light having a plurality of centroid wavelengths, respectively, may be obtained. As indicated above, however, the human eye may perceive a fixed (time averaged) centroid wavelength, as the change (here especially change time) between the at least two centroid wavelengths may be withing 0.025 seconds, more especially within about 0.02 seconds, even more especially within a time period of 0.0167 seconds. The time periods, i.e. the first time period and the second time period may each independently selected from the range of at maximum 0.025 seconds, more especially at maximum 0.02 seconds, yet even more especially at maximum 00167 seconds. However, the change time and/or the time periods may also be much shorter, such as at least 10 times shorter.

Hence, the first VCSEL(s) may be operated continuously or pulsed.

The sweeping change may essentially be a continuous change from one centroid wavelength to the other, and vice versa. The sweeping change may also be a step wise change, especially including a plurality of intermediate centroid wavelengths. When a stepwise change applies, the steps may be at maximum 5 nm, such as at maximum 2 nm.

When the system comprises a single first vertical cavity surface emitting laser, this may apply to the single first vertical cavity surface emitting lasers. When the system comprises a plurality of first vertical cavity surface emitting lasers, this may apply to each of the first vertical cavity surface emitting lasers.

In specific embodiments, for each of the first vertical cavity surface emitting lasers may apply than the change may be a sweeping change, wherein during a time period of especially at maximum 0.025 seconds, such as at maximum about 0.02 seconds, like especially at maximum 0.0167 seconds, the VCSELs sweep between (at least) two spectral power distributions, one having a first centroid wavelength λ_{nc,1}, and one having a second centroid wavelength λ_{nc,2}. Note that when n is two or more, at least two of the first VCSEL may have only partly or even non overlapping wavelength ranges defined by the (respective) first centroid wavelength λ_{nc,1} and the (respective) second centroid wavelength λ_{nc,2}.

The system may also comprise one or more other vertical cavity surface emitting lasers (see also below). However, for the first vertical cavity surface emitting lasers may especially apply that each of the n first vertical cavity surface emitting lasers may be configured to generate ((in a first operational mode of the light generating system) first laser light changing between at least two centroid wavelengths (λ_{nc,1}, λ_{nc,2}) having a wavelength difference of at least 10 nm, with a changing frequency of at least 50 Hz. The phrase “each of the n first vertical cavity surface emitting lasers is configured to generate ((in a first operational mode of the light generating system) first laser light changing between at least two centroid wavelengths (λ_{nc,1}, λ_{nc,2})”, and similar phrases may in embodiments also refer to systems comprising two or more first vertical cavity surface emitting lasers, wherein (in the first operational mode) the spectral power distributions average over time differ, or may even essentially always differ (during the first operational mode). Hence, in embodiments, wherein n is at least 2, (during the first operational mode) at least one of the n first vertical cavity surface emitting lasers is configured to provide the first laser light averaged over time as an emission band, wherein the first laser light has a (first) time dependent centroid wavelength (λ_{1ct}) varying over time between the first centroid wavelength (λ_{1c,1)} and the second centroid wavelength (λ_{1c,2}), and (during the first operational mode) at least another one of the n first vertical cavity surface emitting lasers is configured to provide the first laser light averaged over time as an emission band, wherein the first laser light has a (second) time dependent centroid wavelength (λ_{2ct}) varying over time between the first centroid wavelength (λ_{2c,1}) and the second centroid wavelength (λ_{2c,2}), wherein especially the first time dependent centroid wavelength (λ_{1ct}) and the second time dependent centroid wavelength (λ_{2ct}), more especially also at least (a) the first centroid wavelengths λ_{1c,1} and λ_{2c,1} and/or (b) second centroid wavelengths λ_{1c,2} and λ_{2c,2} differ. Similar considerations may apply when n=3 or higher. In specific embodiments, there may be at least three different first VCSELs.

In specific embodiments, colors or color points of a first type of light and a second type of light may be different when the respective color points of the first type of light and the second type of light differ with at least 0.01 for u′ and/or with at least 0.01 for v′, even more especially at least 0.02 for u′ and/or with at least 0.02 for v′. In yet more specific embodiments, the respective color points of first type of light and the second type of light may differ with at least 0.03 for u′ and/or with at least 0.03 for v′. Here, u‘ and v’ are color coordinate of the light in the CIE 1976 UCS (uniform chromaticity scale) diagram.

More especially, as also elucidate below, when n is at least 2, the time averaged spectral power distributions of the first laser light of at least 2 of the at least 2 vertical cavity surface emitting laser may only partly overlap, or may substantially not overlap.

As indicated above, the system may further comprise a control system. Especially, the control system is configured to control the n first vertical cavity surface emitting lasers.

The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g. measuring, displaying, actuating, opening, shifting, changing temperature, etc.. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions form a remote control. In embodiments, the control system may be controlled via an App on a device, such as a portable device, like a Smartphone or I-phone, a tablet, etc. The device is thus not necessarily coupled to the lighting system, but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, that can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

Especially, in embodiments the control system may be configured to control the n first vertical cavity surface emitting lasers such that (in the first operational mode) of the light generating system) system light may be generated comprising the first laser light of at least one of the n first vertical cavity surface emitting lasers. When n is at least two, especially in embodiments the control system may be configured to control the n first vertical cavity surface emitting lasers such that (in the first operational mode) of the light generating system) system light may be generated comprising the first laser light of at least two of the n first vertical cavity surface emitting lasers.

Further, (in the first operational mode) one or more of the n first vertical cavity surface emitting lasers, together with the second light generating device and optionally together with other light sources and/or optionally together with a luminescent material, may be controlled such that (in the first operational mode), the system light comprises at least the first laser light of the one or more of the n first vertical cavity surface emitting lasers. Further, especially the system light (in the first operational mode) may be white light.

The second light generating device may comprise one or more additional first vertical cavity surface emitting lasers such that n≥2, preferably n≥3, more preferably n≥4, even more preferably n≥5, such as n≥6, or n≥8 or n≥10. Alternatively, the second light generating device may comprise one or more solid state light sources, such as light emitting diodes. In embodiments, the second light generating device may comprise one or more light emitting diodes configured to generate blue light and one or more luminescent materials configured to convert at least part of the blue light into luminescent material light that may comprise one or more of yellow light, green light, orange light and red light. The second light generating device may be configured such that the second light generating device light has an emission band with a full width half maximum of at least 40 nm, preferably more than 60 nm, more preferably more than 80 nm, even more preferably more than 90 nm.

The term white light, and similar terms, herein, is known to the person skilled in the art. It especially relates to light having a correlated color temperature (CCT) between about 1800 K and 20000 K, like at least about 2000 K, especially in the range of 2700-20000 K, for general lighting especially in the range of about 1800-6800 K, like at least about 2000 K, such as 2700-6500 K, and for backlighting purposes especially in the range of about 6500 K and 20000 K, and especially within about 15 SDCM (standard deviation of color matching) from the BBL (black body locus), especially within about 10 SDCM from the BBL, even more especially within about 5 SDCM from the BBL.

With the present invention, it may also be possible to select or in embodiments to control the spectral power distribution. Hence, in embodiments the CCT may be equal to or larger than 1800 K. In further embodiments, the CCT may be equal to or smaller than 8000 K. Further, the color rendering index may especially be at least 60, such as at least 65, like even more especially at least about 70. Therefore, in specific embodiments the control system may be configured to control a spectral power distribution of the system light, wherein (in the first operational mode), the system light may be white light having a correlated color temperature in a range from 1800 K to 8000 K and a color rendering index of at least 70. The phrase “the control system may be configured to control a spectral power distribution of the system light” and similar phrases, may especially indicate that the VCSEL is controlled such that, optionally together with other light sources and/or optionally together with a luminescent material, the system light can be white light.

The fact that the system may be configured to generate white light may not exclude that the system may further be configured to generate colored light. Likewise, the fact that the system may be configured to generate system light having a correlated color temperature in a range from 1800 K to 8000 K and a color rendering index of at least 70, does not exclude that the system may also be configured to generate system light not having a correlated color temperature in a range from 1800 K to 8000 K and/or not having a color rendering index of at least 70. Hence, the system may in embodiments be operated in a single operational mode (especially indicated as first operational mode), and in other embodiments may allow more than one operational modes.

Especially, in embodiments one or more, more especially each, of the n first vertical cavity surface emitting lasers is configured to generate ((in a first operational mode of the light generating system) first laser light changing between at least two centroid wavelengths (λ_{nc,1}, λ_{nc,2}) having a wavelength difference of at least 10 nm, more especially of at least 20 nm. When n is at least 2, at least two of the n first vertical cavity surface emitting lasers may be configured to generate first laser light changing between at least two centroid wavelengths (λ_{nc,1}, λ_{nc,2}) having a wavelength difference of at least 10 nm, in different parts of the visible wavelength range. Hence, the spectral ranges defined by at least two centroid wavelengths (λ_{nc,1}, λ_{nc,2}) for the different first vertical cavity surface emitting lasers may partly overlap or may not overlap.

As indicated above, in embodiments (in the first operational mode) at least one of the one or more first vertical cavity surface emitting lasers may sweep between a first centroid wavelength (λ_{nc,1}) and a second centroid wavelength (λ_{nc,2}). Therefore, in specific embodiments (during the first operational mode) the at least one of the n first vertical cavity surface emitting lasers may be configured to provide the first laser light averaged over time as an emission band, wherein the first laser light has a time dependent centroid wavelength (λ_{nct}) varying over time between the first centroid wavelength (λ_{nc,1}) and the second centroid wavelength (λ_{nc,2}). In specific embodiments wherein n is at least 2, at least two of the n first vertical cavity surface emitting lasers may be configured to provide the first laser light averaged over time as an emission band, wherein the first laser light has a time dependent centroid wavelength (λ_{nct}) varying over time between the first centroid wavelength (λ_{nc,1}) and the second centroid wavelength (λ_{nc,2}), wherein especially the time dependent centroid wavelengths (λ_{nct}) of the at least two of the n first vertical cavity surface emitting lasers differ.

The band shape of the emission band may be controlled by the control system.

Hence, in embodiments the band shape may be substantially conformal to part of the spectral power distribution of a black body radiator (emission) at a specific temperature. For instance, in embodiments the at least one of the one or more first vertical cavity surface emitting lasers may sweep between a first centroid wavelength (λ_{nc,1}) and a second centroid wavelength (λ_{nc,2}) and the intensity may be selected such that the band has a band shape wherein the peak height may essentially be conformal to the spectral power distribution of black body radiation (at a specific temperature). Hence, the spectral power distribution between the first centroid wavelength (λ_{nc,1}) and the second centroid wavelength (λ_{nc,2}) may be conformal to the spectral power distribution of a black body radiator (emission) at a specific temperature. The specific CCT may be selected from the range of 1800-8000 K, and may in specific embodiments also be controllable.

Here, “conformal may mean that averaged over the wavelength, in the wavelength range defined by the first centroid wavelength (λ_{nc,1}) and the second centroid wavelength (λ_{nc,2}) the average distance to the BBL is within 10 SDCM. In more specific embodiments, within about 5 SDCM from the BBL, such as even within about 3 SDCM from the BBL.

In specific embodiments, the spectral power distribution of the system light in the visible may be divided in k wavelength ranges (of equal widths in nanometers), wherein k may be at least 10. For instance, the wavelength range of 380-780 nm may be divided in 40 ranges of each 10 nm, or in 80 ranges of each 5 nm. The value of k may essentially be unlimited. For instance, k may be 400 or larger, like 4000 or larger. Especially, for at least 10%, more especially at least 20%, yet even more especially at least 30%, like even more especially at least 40% of these k wavelength ranges may apply that over the entire wavelength range (of such wavelength range) the intensity in those parts is always within 10 SDCM of the BBL for a specific CCT, such as within 5 SDCM. Yet even more especially for at least 50% of these k wavelength ranges, such as even more especially for at least 60%, like at least 70%, may apply that over the entire wavelength range the intensity in those parts is always within 10 SDCM of the BBL for a specific CCT such as within 5 SDCM. In this way, a substantial part of the spectral power distribution of the system light, in the visible wavelength range, may be conformal to spectral power distribution of the emission of a black body radiator at specific temperature.

Therefore, in specific embodiments each of the n first vertical cavity surface emitting lasers is configured to generate ((in a first operational mode of the light generating system) first laser light changing between at least two centroid wavelengths (λ_{nc,1}, λ_{nc,2}) having a wavelength difference of at least 20 nm, wherein at least one of the n first vertical cavity surface emitting lasers is configured to generate (in the operational mode) first time periods of first laser light having a first centroid wavelength (λ_{nc,1}) and second time periods of first laser light having a second centroid wavelength (λ_{nc,2}), each with a time period frequency of at least 50 Hz; wherein (during the first operational mode) the at least one of the n first vertical cavity surface emitting lasers is configured to provide the first laser light averaged over time as an emission band, wherein the first laser light has a time dependent centroid wavelength (λ_{nct}) varying over time between the first centroid wavelength (λ_{nc,1}) and the second centroid wavelength (λ_{nc,2}), wherein a spectral power distribution of the first laser light averaged over time is conformal to the spectral power distribution of the emission of a black body radiator at specific temperature in the range of 1800-8000 K (especially the CCT).

In embodiments, n is at least 2, such as 2, or 3, or 4. Especially, the (at least) two first vertical cavity surface emitting lasers may generate time averaged emission bands that only partly overlap, such as at maximum 50%, more especially at maximum 25%, yet even more especially at maximum 10%, yet even more especially at maximum 5%. The phrase “different wavelength ranges which wavelength ranges overlap less than 50%”, and similar phrases, may indicate that each of two emission bands overlap less than 50% with the other of the two emission bands. Therefore, in specific embodiments the system may comprise at least two first vertical cavity surface emitting lasers configured to generate (in the first operational mode) of the light generating system) first laser light changing between the at least two centroid wavelengths (λ_{nc,1}, λ_{nc,2}) in at least two different wavelength ranges which wavelength ranges overlap less than 50%.

In specific embodiments, 1≤n≤16, more especially 2≤n≤16, such as 2≤n≤12, like especially 3≤n≤12.

Especially, the time averaged centroid wavelengths may be selected from different wavelength ranges. In such embodiments, the overlap may be very small, or even essentially zero. Therefore, in specific embodiments the system may comprise at least two (i.e. n≥2) first vertical cavity surface emitting lasers configured to generate (in the first operational mode) of the light generating system) first laser light having different time averaged centroid wavelengths (λ_{nac}) selected from (different) wavelength ranges of the group of 440-495 nm, 495-570 nm, 570-590 nm, 590-620 nm, and 620-780 nm. Yet in further specific embodiments, the at least two time averaged centroid wavelengths (λ_{nac}) may differ at least 110 nm. For instance, one first vertical cavity surface emitting laser may be configured to generate (in the first operational mode) of the light generating system) first laser light having a time averaged centroid wavelengths (λ_{nac}) selected from the wavelength range of 440-495 nm, and another first vertical cavity surface emitting laser may be configured to generate (in the first operational mode) of the light generating system) first laser light having a time averaged centroid wavelengths (λ_{nac}) selected from the wavelength range of 620-780 nm. Such embodiment does not exclude yet a further first vertical cavity surface emitting laser may be configured to generate (in the first operational mode) of the light generating system) first laser light having a time averaged centroid wavelengths (λ_{nac}) selected from the wavelength ranges of the group of 495-570 nm and 570-590 nm.

Therefore, in specific embodiments the system may comprise at least three (n≥3) vertical cavity surface emitting lasers configured to generate (in the first operational mode) of the light generating system) first laser light having different time averaged centroid wavelengths (λ_{nac}) selected from (different) wavelength ranges of the group of 440-495 nm, 495-570 nm, 570-590 nm, 590-620 nm, and 620-780 nm, wherein at least three time averaged centroid wavelengths (λ_{nac}) mutually differ at least 40 nm. For instance, the different time averaged centroid wavelengths (λ_{nac}) may be selected from the range of (a) 460 nm+/−20 nm, (b) 550 nm+/−25 nm, and (c) 620 nm+/−30 nm.

The phrase “time averaged centroid wavelengths (λ_{nac})” and similar phrases may especially refer to the centroid wavelength which would e.g. observed when measured over a time period of at least 1/50 Hz, i.e. over a time period of at least 0.02 seconds, like averaged over a time period selected from the range of 0.2-2 seconds. In such time period, the specific VCSEL may have changed a plurality of times between the at least two centroid wavelengths, leading to a time averaged centroid wavelengths (λ_{nac}) which may be perceived by the human eye.

In this way, over the wavelength range in the visible, at several wavelength ranges in the spectrum, the first VCSELs may generate spectral power distributions which together may provide (in the first operational mode) the system light, which may thus in specific embodiments be white light. In specific embodiments, in this way at least parts of the spectral power distribution may substantially be conformal to the spectral power distribution of a black body radiator (emission) at a specific temperature.

In specific embodiments, the n first vertical cavity surface emitting lasers are configured to generate (in the first operational mode) system light having radiant flux at at least four different wavelengths in the wavelength range of 380-780 nm, wherein a smallest and a largest wavelength where the n first vertical cavity surface emitting lasers provide intensity span a wavelength range of at least 110 nm; wherein averaged over time at least 50% of a radiant flux of the first laser light is at the at least 4 different wavelength ranges within the range of 380-780 nm. Especially, this may be obtained with four different VCSELs, but dependent upon the wavelength range controllability of the VCSELs, this may also be achieved with more or less VCSELs. For instance, these wavelength ranges may be selected from the group of 440-495 nm, 495-570 nm, 570-590 nm, 590-620 nm, and 620-780 nm. Especially, when there are more than four different wavelength ranges where intensity is provided, in each of these four wavelength ranges intensity may be provided. In this way, a substantially continuous spectral power distribution may be provided of the system light.

More especially, in embodiments (in the first operational mode) at least one of the n first vertical cavity surface emitting lasers may be configured to generate first laser light wherein averaged over time at least 50% of a radiant flux of the first laser light is within at least 6 different non-overlapping wavelength ranges of at least 10 nm width within the range of 380-780 nm. Especially, this may be obtained with six different VCSELs, but dependent upon the wavelength range controllability of the VCSELs, this may also be achieved with more or less VCSELs. For instance, these wavelength ranges may be selected from the group of 440-495 nm, 495-570 nm, 570-590 nm, 590-620 nm, and 620-780 nm. Especially, in each of these four wavelength ranges of 440-495 nm, 495-570 nm, 570-590 nm, 590-620 nm, and 620-780 nm intensity may be provided. In this way, a substantially continuous spectral power distribution may be provided.

Yet, more especially in embodiments (in the first operational mode) at least one of the n first vertical cavity surface emitting lasers may be configured to generate first laser light wherein averaged over time at least 60% of a radiant flux of the first laser light is within at least 8 different non-overlapping wavelength ranges of at least 10 nm width within the range of 380-780 nm. Especially, this may be obtained with eight different VCSELs, but dependent upon the wavelength range controllability of the VCSELs, this may also be achieved with more or less VCSELs. For instance, these wavelength ranges may be selected from the group of 440-495 nm, 495-570 nm, 570-590 nm, 590-620 nm, and 620-780 nm. Especially, in each of these four wavelength ranges of 440-495 nm, 495-570 nm, 570-590 nm, 590-620 nm, and 620-780 nm intensity may be provided. In this way, a substantially continuous spectral power distribution may be provided. More especially, (in the first operational mode) at least one of the n first vertical cavity surface emitting lasers may be configured to generate first laser light wherein averaged over time at least 70%, such as at least 80% of a radiant flux of the first laser light is within at least 8 different non-overlapping wavelength ranges of at least 10 nm width within the range of 380-780 nm.

Further, in more specific embodiments (in the first operational mode) at least one of the n first vertical cavity surface emitting lasers is configured to generate first laser light wherein averaged over time at least 80% of a radiant flux of the first laser light is within at least 11 different non-overlapping wavelength ranges of at least 10 nm width within the range of 380-780 nm. Especially, this may be obtained with eight different VCSELs, but dependent upon the wavelength range controllability of the VCSELs, this may also be achieved with more or less VCSELs. For instance, these wavelength ranges may be selected from the group of 440-495 nm, 495-570 nm, 570-590 nm, 590-620 nm, and 620-780 nm. Especially, in each of these four wavelength ranges of 440-495 nm, 495-570 nm, 570-590 nm, 590-620 nm, and 620-780 nm intensity may be provided. In this way, a substantially continuous spectral power distribution may be provided. More especially, (in the first operational mode) at least one of the n first vertical cavity surface emitting lasers is configured to generate first laser light wherein averaged over time at least 90% of a radiant flux of the first laser light is within at least 11 different non-overlapping wavelength ranges of at least 10 nm width within the range of 380-780 nm.

In embodiments, the system may provide the system light only with the one or more First VCSELs, such as with at least 2 different First VCSELs, more especially with at least 3 different First VCSELs, such as in more specific embodiments at least 4 different First VCSELs. However, in other embodiments also a luminescent material may be comprise by the system, which luminescent material may be configured to convert at least part of the light of one of the first VCSELSs and/or another light source.

Therefore, in embodiments the system may further comprise a luminescent material configured to convert at least part of the light of a second light generating device, wherein (in the first operational mode), the system light comprises the luminescent material light, and wherein the luminescent material light in specific embodiments may comprise an emission band having a full width half maximum of at least 30 nm, such as more especially at least 40 nm, such as in more specific embodiments at least 60 nm.

Alternatively or additionally, the system may further comprise a luminescent material configured to convert at least part of the light of at least one of the n first vertical cavity surface emitting lasers, wherein (in the first operational mode), the system light may comprise the luminescent material light, and wherein the luminescent material light comprises an emission band having a full width half maximum of at least 30 nm, such as more especially at least 40 nm, such as in more specific embodiments at least 60 nm. Hence, the laser light of one or more first VCSELs of the at least one first VCSELs may (at least partly) be used to convert into luminescent material light.

The term “luminescent material” especially refers to a material that can convert first radiation, especially one or more of UV radiation and blue radiation, into second radiation. In general, the first radiation and second radiation have different spectral power distributions. Hence, instead of the term “luminescent material”, also the terms “luminescent converter” or “converter” may be applied. In general, the second radiation has a spectral power distribution at larger wavelengths than the first radiation, which is the case in the so-called down-conversion. In specific embodiments, however the second radiation has a spectral power distribution with intensity at smaller wavelengths than the first radiation, which is the case in the so-called up-conversion.

In embodiments, the “luminescent material” may especially refer to a material that can convert radiation into e.g. visible and/or infrared light. For instance, in embodiments the luminescent material may be able to convert one or more of UV radiation and blue radiation, into visible light. The luminescent material may in specific embodiments also convert radiation into infrared radiation (IR). Hence, upon excitation with radiation, the luminescent material emits radiation. In general, the luminescent material will be a down converter, i.e. radiation of a smaller wavelength is converted into radiation with a larger wavelength (λₑₓ<λₑₘ), though in specific embodiments the luminescent material may comprise up-converter luminescent material, i.e. radiation of a larger wavelength is converted into radiation with a smaller wavelength (λₑₓ≥λₑₘ).

In embodiments, the term “luminescence” may refer to phosphorescence. In embodiments, the term “luminescence” may also refer to fluorescence. Instead of the term “luminescence”, also the term “emission” may be applied. Hence, the terms “first radiation” and “second radiation” may refer to excitation radiation and emission (radiation), respectively. Likewise, the term “luminescent material” may in embodiments refer to phosphorescence and/or fluorescence.

The term “luminescent material” may also refer to a plurality of different luminescent materials. Examples of possible luminescent materials are indicated below. Hence, the term “luminescent material” may in specific embodiments also refer to a luminescent material composition.

In embodiments, luminescent materials are selected from garnets and nitrides, especially doped with trivalent cerium or divalent europium, respectively. The term “nitride” may also refer to oxynitride or nitridosilicate, etc.

In specific embodiments the luminescent material comprises a luminescent material of the type A₃B₅O₁₂:Ce, wherein A in embodiments comprises one or more of Y, La, Gd, Tb and Lu, especially (at least) one or more of Y, Gd, Tb and Lu, and wherein B in embodiments comprises one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, especially suitable luminescent materials are cerium comprising garnet materials. Embodiments of garnets especially include A₃B₅O₁₂ garnets, wherein A comprises at least yttrium or lutetium and wherein B comprises at least aluminum. Such garnets may be doped with cerium (Ce), with praseodymium (Pr) or a combination of cerium and praseodymium; especially however with Ce. Especially, B comprises aluminum (Al), however, B may also partly comprise gallium (Ga) and/or scandium (Sc) and/or indium (In), especially up to about 20% of Al, more especially up to about 10% of Al (i.e. the B ions essentially consist of 90 or more mole % of Al and 10 or less mole % of one or more of Ga, Sc and In); B may especially comprise up to about 10% gallium. In another variant, B and O may at least partly be replaced by Si and N. The element A may especially be selected from the group consisting of yttrium (Y), gadolinium (Gd), terbium (Tb) and lutetium (Lu). Further, Gd and/or Tb are especially only present up to an amount of about 20% of A. In a specific embodiment, the garnet luminescent material comprises (Y₁₋ₓLuₓ)₃B₅O₁₂:Ce, wherein x is equal to or larger than 0 and equal to or smaller than 1. The term “:Ce”, indicates that part of the metal ions (i.e. in the garnets: part of the “A” ions) in the luminescent material is replaced by Ce. For instance, in the case of (Y₁₋ₓLuₓ)₃Al₅O₁₂:Ce, part of Y and/or Lu is replaced by Ce. This is known to the person skilled in the art. Ce will replace A in general for not more than 10%; in general, the Ce concentration will be in the range of 0.1 to 4%, especially 0.1 to 2% (relative to A). Assuming 1% Ce and 10% Y, the full correct formula could be (Y_{0.1}Lu_{0.89}Ce_{0.01})₃Al₅O₁₂. Ce in garnets is substantially or only in the trivalent state, as is known to the person skilled in the art.

In embodiments, the luminescent material (thus) comprises A₃B₅O₁₂ wherein in specific embodiments at maximum 10% of B—O may be replaced by Si—N.

In specific embodiments the luminescent material comprises (Yₓ₁₋ₓ₂₋ₓ₃A′ₓ₂Ceₓ₃)₃(Al_{y1-y2}B′_{y2})₅O₁₂, wherein x1+x2+x3=1, wherein x3>0, wherein 0<x2+x3≤0.2, wherein y1+y2=1, wherein 0≤y2≤0.2, wherein A′ comprises one or more elements selected from the group consisting of lanthanides, and wherein B′ comprises one or more elements selected from the group consisting of Ga, In and Sc. In embodiments, x3 is selected from the range of 0.001-0.1. In the present invention, especially x1>0, such as >0.2, like at least 0.8. Garnets with Y may provide suitable spectral power distributions.

In specific embodiments at maximum 10% of B—O may be replaced by Si—N. Here, B in B—O refers to one or more of Al, Ga, In and Sc (and O refers to oxygen); in specific embodiments B—O may refer to Al—O. As indicated above, in specific embodiments x3 may be selected from the range of 0.001-0.04. Especially, such luminescent materials may have a suitable spectral distribution (see however below), have a relatively high efficiency, have a relatively high thermal stability, and allow a high CRI (optionally in combination with (the) light of other sources of light as described herein). Hence, in specific embodiments A may be selected from the group consisting of Lu and Gd. Alternatively or additionally, B may comprise Ga. Hence, in embodiments the luminescent material comprises (Yₓ₁₋ₓ₂₋ₓ₃(Lu,Gd)ₓ₂Ceₓ₃)₃(Al_{y1-y2}Ga_{y2})₅O₁₂, wherein Lu and/or Gd may be available. Even more especially, x3 is selected from the range of 0.001-0.1, wherein 0<x2+x3≤0.1, and wherein 0≤y2≤0.1. Further, in specific embodiments, at maximum 1% of B—O may be replaced by Si—N. Here, the percentage refers to moles (as known in the art); see e.g. also EP3149108. In yet further specific embodiments, the luminescent material comprises (Yₓ₁₋ₓ₃Ceₓ₃)₃Al₅O₁₂, wherein x1+x3=1, and wherein 0<x3≤0.2, such as 0.001-0.1.

In specific embodiments, the light generating device may only include luminescent materials selected from the type of cerium comprising garnets. In even further specific embodiments, the light generating device includes a single type of luminescent materials, such as (Yₓ₁₋ₓ₂₋ₓ₃A′ₓ₂Ceₓ₃)₃(Al_{y1-y2}B′_{y2})₅O₁₂. Hence, in specific embodiments the light generating device comprises luminescent material, wherein at least 85 weight %, even more especially at least about 90 wt. %, such as yet even more especially at least about 95 weight % of the luminescent material comprises (Yₓ₁₋ₓ₂₋ₓ₃A′ₓ₂Ceₓ₃)₃(Al_{y1-y2}B′_{y2})₅O₁₂. Here, wherein A′ comprises one or more elements selected from the group consisting of lanthanides, and wherein B′ comprises one or more elements selected from the group consisting of Ga, In and Sc, wherein x1+x2+x3=1, wherein x3>0, wherein 0<x2+x3≤0.2, wherein y1+y2=1, wherein 0≤y2≤0.2. Especially, x3 is selected from the range of 0.001-0.1. Note that in embodiments x2=0. Alternatively or additionally, in embodiments y2=0.

In specific embodiments, A may especially comprise at least Y, and B may especially comprise at least Al.

Therefore, in specific embodiments the luminescent material may comprise a luminescent material of the type A₃B₅O₁₂:Ce, wherein A comprises one or more of Y, La, Gd, Tb and Lu, and wherein B comprises one or more of Al, Ga, In and Sc.

Alternatively or additionally, wherein the luminescent material may comprises a luminescent material of the type A₃Si₆N₁₁:Ce³⁺, wherein A comprises one or more of Y, La, Gd, Tb and Lu, such as in embodiments one or more of La and Y.

In embodiments, the luminescent material may alternatively or additionally comprise one or more of M₂Si₅N₈:Eu²⁺ and/or MAlSiN₃:Eu²⁺ and/or Ca₂AlSi₃O₂N₅:Eu²⁺ etc., wherein M comprises one or more of Ba, Sr and Ca, especially in embodiments at least Sr. Hence, in embodiments, the luminescent may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba. The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca). Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Eu in the above indicated luminescent materials is substantially or only in the divalent state, as is known to the person skilled in the art.

In embodiments, a red luminescent material may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba.

The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca).

Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Eu in the above indicated luminescent materials is substantially or only in the divalent state, as is known to the person skilled in the art.

Blue luminescent materials may comprise YSO (Y₂SiO₅:Ce³⁺), or similar compounds, or BAM (BaMgAl₁₀O₁₇:Eu²⁺), or similar compounds.

The term “luminescent material” herein especially relates to inorganic luminescent materials.

Instead of the term “luminescent material” also the term “phosphor”. These terms are known to the person skilled in the art.

Alternatively or additionally, also other luminescent materials may be applied. For instance quantum dots and/or organic dyes may be applied and may optionally be embedded in transmissive matrices like e.g. polymers, like PMMA, or polysiloxanes, etc. etc.

Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with a shell such as cadmium sulfide (CdS) and zinc sulfide (ZnS). Cadmium free quantum dots such as indium phosphide (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in the present invention. However, it may be preferred for reasons of environmental safety and concern to use cadmium-free quantum dots or at least quantum dots having a very low cadmium content.

Instead of quantum dots or in addition to quantum dots, also other quantum confinement structures may be used. The term “quantum confinement structures” should, in the context of the present application, be understood as e.g. quantum wells, quantum dots, quantum rods, tripods, tetrapods, or nano-wires, etcetera.

Organic phosphors can be used as well. Examples of suitable organic phosphor materials are organic luminescent materials based on perylene derivatives, for example compounds sold under the name Lumogen® by BASF. Examples of suitable compounds include, but are not limited to, Lumogen® Red F305, Lumogen® Orange F240, Lumogen® Yellow F083, and Lumogen® F170.

Different luminescent materials may have different spectral power distributions of the respective luminescent material light. Alternatively or additionally, such different luminescent materials may especially have different color points (or dominant wavelengths).

As indicated above, other luminescent materials may also be possible. Hence, in specific embodiments the luminescent material is selected from the group of divalent europium containing nitrides, divalent europium containing oxynitrides, divalent europium containing silicates, cerium comprising garnets, and quantum structures. Quantum structures may e.g. comprise quantum dots or quantum rods (or other quantum type particles) (see above). Quantum structures may also comprise quantum wells. Quantum structures may also comprise photonic crystals.

The phrase, “one or more first VCSELs of the at least one first VCSELs” and similar phrases may also be indicated as “k1 first VCSELs of the n first VCSELs”, wherein n≥1, and wherein 1≤k1≤n.

Alternatively or additionally, the system may comprise another light source, of which the light as such may be comprised by the system light. Whereas the first light sources may provide first laser light have a time variable centroid wavelength, in embodiments such another light source may be configured to generate light source light having an essentially fixed centroid wavelength, e.g. a laser diode. In embodiments, the system may further comprise a third light generating device configured to generate third device light, wherein the third light generating device may comprise a laser, wherein the third device light may have a third device light centroid wavelength (λ_{c3}) which is at a fixed position (during the first operational mode), wherein the n first vertical cavity surface emitting lasers may be configured to generate (in the first operational mode) of the light generating system) first laser light having time averaged centroid wavelength(s) (λ_{nac}), especially wherein the third device light centroid wavelength (λ_{c3}) may differ from at least one of the time averaged centroid wavelength(s) (λ_{nac}) of the first laser light of the n first vertical cavity surface emitting lasers. The term “fixed position” may especially imply that at frequencies higher than 50 Hz, the spectral position of the third device light may essentially be fixed, such as e.g. with differences of at maximum 0.03 for u′ and/or with at maximum 0.03 for v′, even more especially at maximum 0.02 for u′ and/or with at maximum 0.02 for v′. In yet more specific embodiments, the respective color points of first type of light and the second type of light may differ with at maximum 0.01 for u′ and/or with at maximum 0.01 for v′. Here, u′ and v′ are color coordinate of the light in the CIE 1976 UCS (uniform chromaticity scale) diagram.

In specific embodiments, the control system may be configured to control the correlated color temperature of the system light (in the first operational mode) at a value selected from the range of 1800-6500 K; wherein the correlated color temperature of the system light is at least controllable over a CCT control range of at least about 300 K, such as more especially at least 500 K within the range of 1800-6500 K.

Hence, in embodiments (in the first operational mode), the CCT of the system light may be selected from a first correlated color temperature (CCT1) and a second correlated color temperature (CCT2), wherein |CCT2−CCT1|≥300K. For instance, 300 K≤|CCT2−CCT1|≤5000 K, such as 800 K≤|CCT2−CCT1|≤4700 K, more especially 1000 K≤|CCT2−CCT1|≤4500 K. In embodiments, (in the first operational mode), the CCT of the system light may be selected from a first correlated color temperature (CCT1) and a second correlated color temperature (CCT2), wherein 1000 K≤|CCT2−CCT1|≤2500 K.

Conformance with the BBL may be achieved by controlling the intensities at different wavelengths such that the spectral power distribution is conformal with the BBL. This may done with one or more of the power provided and/or by controlling the duty cycle.

In specific embodiments, the control system may be configured to control the color rendering index of the system light (in the first operational mode) at a value of at least 70, more especially at least 80, even more especially at least 90; wherein controlling the spectral power distribution of the system light (in the operational mode) comprises individually controlling a duty cycle of first pules and a duty cycle of the second time periods.

In embodiments, R9 may be at least 0, such as even more especially at least 30. Alternatively, the R9 value may be controllable, such as over a range of at least 20 (like e.g. between 20-40). Yet, in further embodiments wherein n≥3, and wherein the control system is configured to control the R9 value of the system light (in the first operational mode) at a value of at least 40; wherein the R9 value is controllable over a R9 control range of at least 30, wherein the R9 control range at least partly overlaps with the range of at least 40; and wherein (in the first operational mode) the color rendering index of the system light is at least 80.

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

In yet a further aspect, the invention also provides a lamp or a luminaire comprising the light generating system as defined herein. The luminaire may further comprise a housing, optical elements, louvres, etc. etc. The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a lighting device selected from the group of a lamp, a luminaire, a projector device, a disinfection device, a photochemical reactor, and an optical wireless communication device, comprising the light generating system as defined herein. The lighting device may comprise a housing or a carrier, configured to house or support, one or more elements of the light generating system. For instance, in embodiments the lighting device may comprise a housing or a carrier, configured to house or support one or more of first VCSELs and the control system.

Therefore, in an aspect the invention also provides a lighting device selected from the group of a lamp, a luminaire, a projector device, a disinfection device, a photochemical reactor, and an optical wireless communication device, comprising the light generating system as defined herein.

The terms “visible”, “visible light” or “visible emission” and similar terms refer to light having one or more wavelengths in the range of about 380-780 nm. Herein, UV may especially refer to a wavelength selected from the range of 190-380 nm, such as 200-380 nm.

The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to (at least) visible light.

The terms “violet light” or “violet emission” especially relates to light having a wavelength in the range of about 380-440 nm. The terms “blue light” or “blue emission” especially relates to light having a wavelength in the range of about 440-495 nm (including some violet and cyan hues). The terms “green light” or “green emission” especially relate to light having a wavelength in the range of about 495-570 nm. The terms “yellow light” or “yellow emission” especially relate to light having a wavelength in the range of about 570-590 nm. The terms “orange light” or “orange emission” especially relate to light having a wavelength in the range of about 590-620 nm. The terms “red light” or “red emission” especially relate to light having a wavelength in the range of about 620-780 nm. The term “pink light” or “pink emission” refers to light having a blue and a red component. The term “cyan” may refer to one or more wavelengths selected from the range of about 490-520 nm. The term “amber” may refer to one or more wavelengths selected from the range of about 585-605 nm, such as about 590-600 nm. The phrase “light having one or more wavelengths in a wavelength range” and similar phrases may especially indicate that the indicated light (or radiation) has a spectral power distribution with at least intensity or intensities at these one or more wavelengths in the indicate wavelength range. For instance, a blue emitting solid state light source will have a spectral power distribution with intensities at one or more wavelengths in the 440-495 nm wavelength range.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1a-1b schematically depict some embodiments and aspects;

FIGS. 2a-2c schematically depict embodiments; FIGS. 2a-2c show spectral power distributions with a CCT of 2700 K, a CRI of 93, and an R9 of 40;

FIGS. 3a-3c schematically depict embodiments and variants; FIGS. 3b-3c show spectral power distributions with a CCT of 2840 K, a CRI of 94, and an R9 of 61; and

FIG. 4 schematically depicts a plurality of embodiments.

The schematic drawings are not necessarily to scale.

### DETAILED DESCRIPTION OF THE EMBODIMENTS

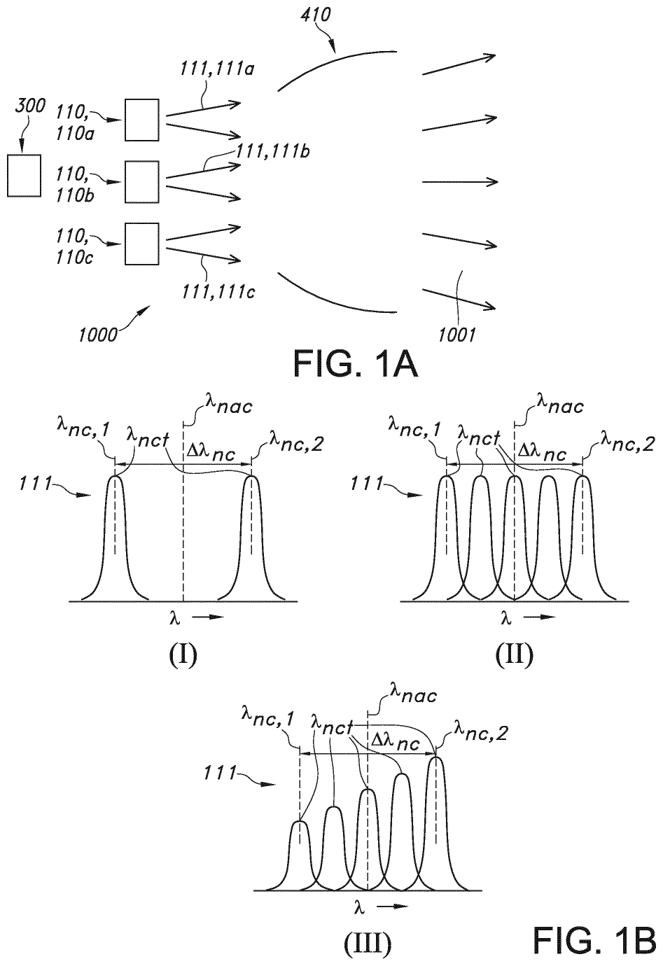

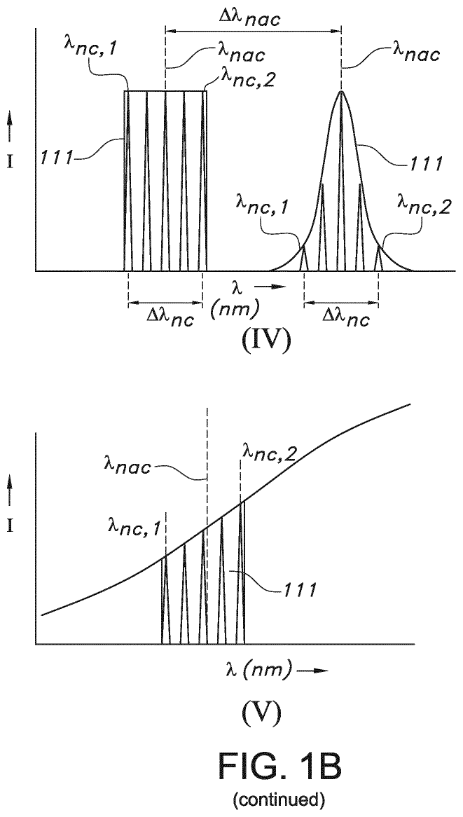

Referring to FIGS. 1a-1b schematically some embodiments and aspects are depicted of and related to a light generating system 1000 comprising n first vertical cavity surface emitting lasers 110 and a control system 300. Especially, n≥1. Here, by way of example n=3.

Each of the n first vertical cavity surface emitting lasers 110 may be configured to generate (in a first operational mode) of the light generating system 1000 first laser light 111. The n first vertical cavity surface emitting lasers 110 are indicated with references 110a, 110b, and 110c. The laser light 111 of the respective n first vertical cavity surface emitting lasers 110 is indicated with references 111a, 111b, and 111c, respectively. The laser light 111a, 111b, and 111c of the respective n first vertical cavity surface emitting lasers 110 may—(during the first operational mode)—change between at least two centroid wavelengths (λ_{nc,1}, λ_{nc,2}) having a wavelength difference of at least 10 nm, see also FIG. 1b. The change may be with a changing frequency of at least 50 Hz.

The dashed rectangle comprised by the first VCSELs 110 may by way of example refer to MEMS, which may be used to control the time dependent spectral power distributions of the (respective) first laser light.

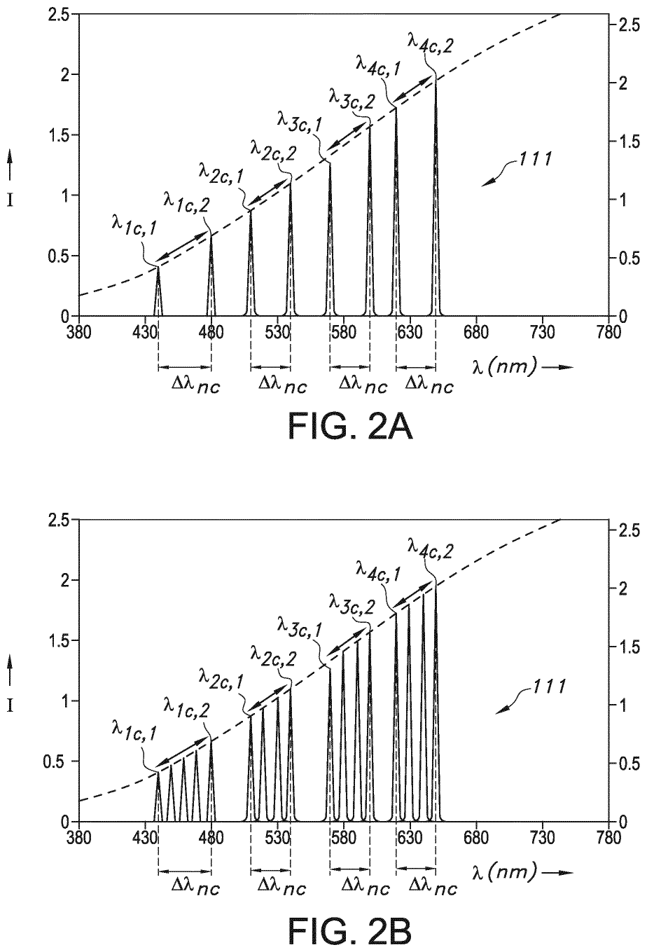

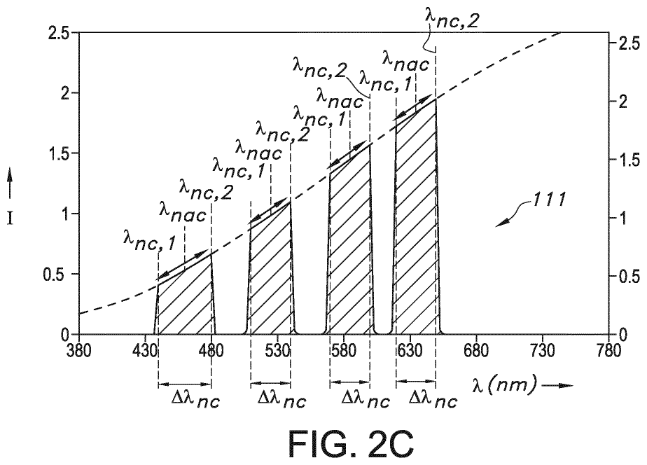

The control system 300 may be configured to control the n first vertical cavity surface emitting lasers 110 such that (in the first operational mode of the light generating system 1000) system light 1001 may be generated comprising the first laser light 111 of at least one of the n first vertical cavity surface emitting lasers 110, see also FIG. 2.

Reference 410 may refer to an optical element. The term “optics” may especially refer to (one or more) optical elements. Hence, the terms “optics” and “optical elements” may refer to the same items. The optics may include one or more or mirrors, reflectors, collimators, lenses, prisms, diffusers, phase plates, polarizers, diffractive elements, gratings, dichroics, arrays of one or more of the afore-mentioned, etc. Alternatively or additionally, the term “optics” may refer to a holographic element or a mixing rod. In embodiments, the optics may include one or more of beam expander optics and zoom lens optics. See further above for examples of optics. The optical element 410 may especially comprise a beam shaping element, like a collector. For instance, the optical element 410 may comprise a CPC (compound parabolic concentrator). Alternatively or additionally, the optical element 410 may comprise a lens.

The control system 300 may be configured to control a spectral power distribution of the system light 1001.

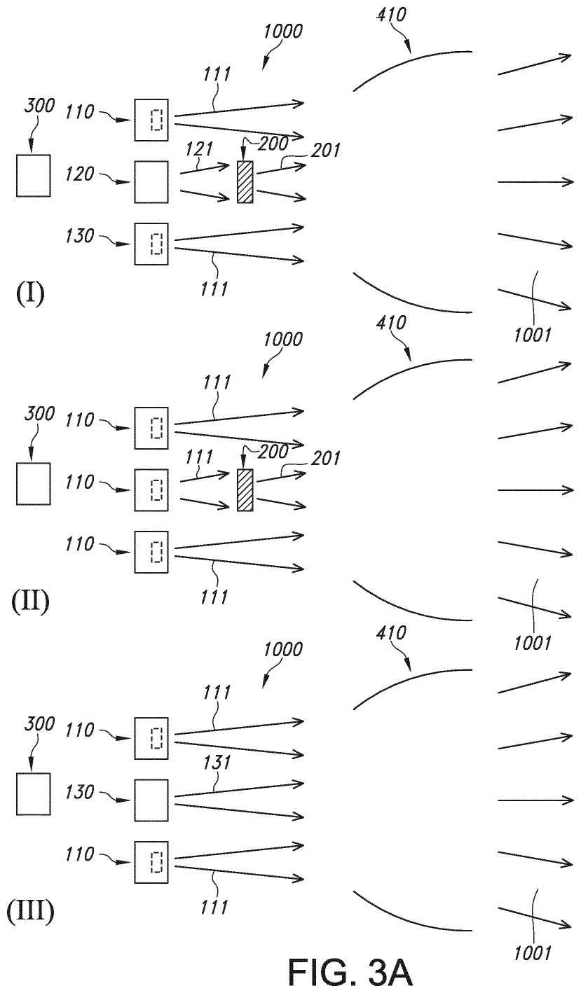

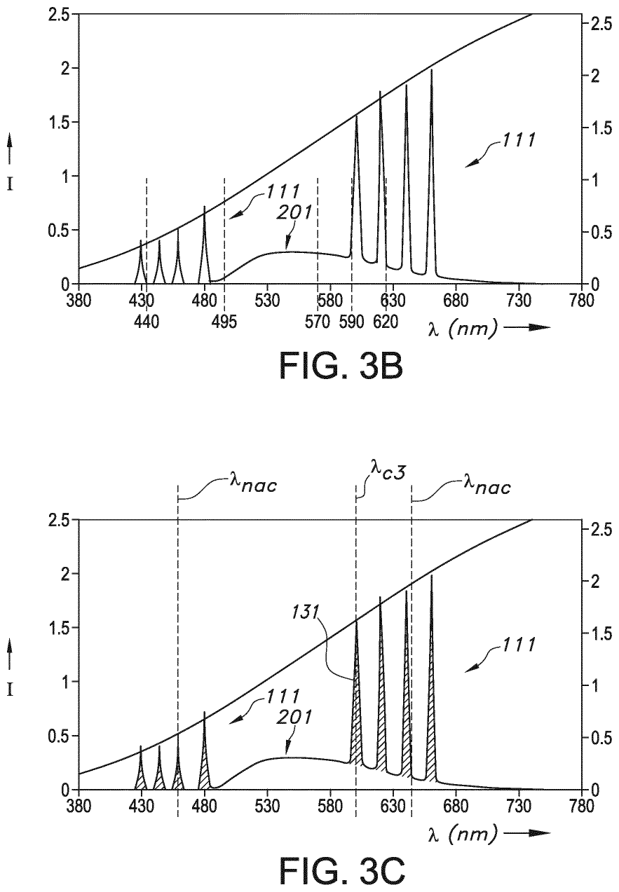

Referring also to e.g. FIGS. 2 and 3, (in the first operational mode), the system light 1001 may be white light having in embodiments a correlated color temperature in a range from 1800 K to 8000 K and a color rendering index of at least 70.

In embodiments, each of the n first vertical cavity surface emitting lasers 110 may be configured to generate (in a first operational mode) of the light generating system 1000 first laser light 111 changing between at least two centroid wavelengths (λ_{nc,1}, λ_{nc,2}) having a wavelength difference of at least 10 nm, such as at least 20 nm.

At least one of the n first vertical cavity surface emitting lasers 110 may be configured to generate (in the operational mode) first time periods of first laser light 111 having a first centroid wavelength (λ_{nc,1}) and second time periods of first laser light 111 having a second centroid wavelength (λ_{nc,2}), each with a time period frequency of at least 50 Hz.

The at least one of the n first vertical cavity surface emitting lasers 110 may be configured to provide the first laser light 111 averaged over time as an emission band (during the first operational mode).

The first laser light 111 may have a time dependent centroid wavelength (λ_{nct}) varying over time between the first centroid wavelength (λ_{nc,1}) and the second centroid wavelength (λ_{nc,2}).

Referring to FIG. 1b, the three schematically depicted embodiments may show the spectral power distributions of a VCSEL at different times. Hence, averaged over time the spectral power distribution may be provided as by way of example provided in the schematic drawings I-III of FIG. 1b, leading to respective time averaged centroid wavelengths λ_{nac}.

A spectral power distribution of the first laser light 111 averaged over time may be conformal to the spectral power distribution of the emission of a black body radiator at specific temperature in the range of 1800-8000 K, or at least part thereof, see also FIGS. 2a-2c.

Referring to FIGS. 2a-2c, in embodiments, the light generating system may comprise at least two first vertical cavity surface emitting lasers 110 configured to generate (in the first operational mode of the light generating system 1000) first laser light 111 changing between the at least two centroid wavelengths (λ_{nc,1}, λ_{nc,2}) in at least two different wavelength ranges which wavelength ranges overlap less than 50%. Especially, the system 1000 may comprise at least two first vertical cavity surface emitting lasers 110 configured to generate (in the first operational mode of the light generating system 1000) first laser light 111 having different time averaged centroid wavelengths (λ_{nac}) selected from (different) wavelength ranges of the group of 440-495 nm, 495-570 nm, 570-590 nm, 590-620 nm, and 620-780 nm. At least two time averaged centroid wavelengths (λ_{nac}) differ at least 110 nm. More especially, in embodiments the system 1000 may comprise at least three vertical cavity surface emitting lasers 110 configured to generate (in the first operational mode of the light generating system 1000) first laser light 111 having different time averaged centroid wavelengths (λ_{nac}) selected from (different) wavelength ranges of the group of 440-495 nm, 495-570 nm, 570-590 nm, 590-620 nm, and 620-780 nm. Yet further, in embodiments at least three time averaged centroid wavelengths (λ_{nac}) may mutually differ at least 40 nm.

FIG. 2a schematically depicts an embodiment wherein the first vertical cavity surface emitting lasers 110 may switch between the at least two centroid wavelengths (k c,₁, λ_{nc,2}) without intermediary centroid wavelengths; FIG. 2b schematically depicts an embodiments wherein the first vertical cavity surface emitting lasers 110 sweep between the (extreme) two centroid wavelengths (λ_{nc,1}, λ_{nc,2}). This may result in a substantially continuous emission band, which is depicted in FIG. 2c.

FIG. 2c shows an embodiments depicting sweeping between the extreme centroid wavelengths (λ_{nc,1}, λ_{nc,2}) wherein the sweeping may essentially be a continuous change in emission wavelength, hence an essentially continuous change in time dependent centroid wavelength, leading to an emission band. This emission band may be essentially to a part of the black body locus at a specific correlated color temperature. In FIGS. 2a-2b, the spectral power distribution of a black body radiator (emission) at a specific temperature is indicated with the dashed line.

Referring to FIG. 2b (and also 2c), in specific embodiments, the spectral power distribution of the system light in the visible may be divided in k wavelength ranges (of equal widths in nanometers), wherein k may be at least 10. For instance, the wavelength range of 380-780 nm may be divided in 40 ranges of each 10 nm, or in 80 ranges of each 5 nm. The value of k may essentially be unlimited. Especially, for at least 10%, more especially at least 20%, yet even more especially at least 30%, like even more especially at least 40% of these k wavelength ranges may apply that over the entire wavelength range the intensity in those parts is always within 10 SDCM of the BBL for a specific CCT, such as within 5 SDCM. Here, in FIGS. 2b-2c, by way of example (at least) 4 ranges of each at least 10 nm, are essentially conformal within 10 SDCM of the BBL for a specific CCT.

Referring to e.g. FIGS. 2a-2c and 3a-3c, the n first vertical cavity surface emitting lasers 110 may in embodiments be configured to generate (in the first operational mode) system light 1001 having radiant flux at least four different wavelengths in the wavelength range of 380-780 nm. Especially, a smallest and a largest wavelength where the n first vertical cavity surface emitting lasers 110 provide intensity span a wavelength range of at least 110 nm. The difference between the extreme centroid wavelengths (λ_{nc,1}, λ_{nc,2}) of a first vertical cavity surface emitting laser 110 is indicated with ref Δλ_{nc}.

In FIGS. 2a-2b wherein n is at least 2, during the first operational mode at least one of the n first vertical cavity surface emitting lasers 110 is configured to provide the first laser light 111 averaged over time as an emission band, wherein the first laser light 111 has a first time dependent centroid wavelength λ_{1ct} varying over time between the first centroid wavelength λ_{1c,1} and the second centroid wavelength λ_{1c,2}, and during the first operational mode at least another one of the n first vertical cavity surface emitting lasers 110 is configured to provide the first laser light 111 averaged over time as an emission band, wherein the first laser light 111 has a second time dependent centroid wavelength λ_{2ct} varying over time between the first centroid wavelength λ_{2c,1} and the second centroid wavelength λ_{2c,2}, wherein especially the first time dependent centroid wavelength λ_{1ct} and the second time dependent centroid wavelength λ_{2ct}, more especially also at least a the first centroid wavelengths λ_{1c,1} and λ_{2c,1} and/or b second centroid wavelengths λ_{1c,2} and λ_{2c,2} differ.

The respective the first centroid wavelength λ_{nc,1} and the second centroid wavelength λ_{nc,2}, are in FIGS. 2a-2b indicated with references λ_{1c,1} and λ_{1c,2}, λ_{2c,1} and λ_{2c,2}, λ_{3c,1} and λ_{3c,2}, and λ_{4c,1} and λ_{4c,2}, for the n=4 first VCSEL.

In embodiments, averaged over time at least 50% of a radiant flux of the first laser light may be (provided) at the at least 4 different wavelength ranges within the range of 380-780 nm.

Referring to FIGS. 2a-2c, in embodiments, (in the first operational mode) at least one of the n first vertical cavity surface emitting lasers 110 may be configured to generate first laser light 111, more especially each of the n first vertical cavity surface emitting lasers 110. Averaged over time at least 50% of a radiant flux of the first laser light may be within at least 6 different non-overlapping wavelength ranges of at least 10 nm width within the range of 380-780 nm. Note that in FIGS. 2a-2c the laser light 111 of only four first vertical cavity surface emitting lasers 110 is schematically depicted, but as will be clear to a person skilled in the art, n may in embodiments also be larger than 4 (or in other embodiments be smaller than 4).

In specific embodiments, (in the first operational mode) at least one of the n first vertical cavity surface emitting lasers 110 may be configured to generate first laser light 111. Especially, together all the n first vertical cavity surface emitting lasers 110 may be configured to generate first laser light 111. Averaged over time at least 60% of a radiant flux of the first laser light may be within at least 8 different non-overlapping wavelength ranges of at least 10 nm width within the range of 380-780 nm. Yet even more especially, in embodiments (in the first operational mode) at least one of the n first vertical cavity surface emitting lasers 110, more especially all n first vertical cavity surface emitting lasers 110 together, may be configured to generate first laser light 111. Especially, averaged over time at least 80% of a radiant flux of the first laser light may be within at least 11 different non-overlapping wavelength ranges of at least 10 nm width within the range of 380-780 nm.

Referring to FIG. 3a, embodiment I, the light generating system 1000 may further comprise a luminescent material 200 configured to convert at least part of the light of a second light generating device 120. The system light 1001 may (in the first operational mode) comprise the luminescent material light 201. In specific embodiments, the luminescent material light 201 may comprise an emission band having a full width half maximum of at least 40 nm. A possible spectral power distribution is schematically depicted in FIG. 3b.

Referring to FIG. 3a, embodiment II, the light generating system 1000 may further comprise a luminescent material 200 configured to convert at least part of the light of at least one of the n first vertical cavity surface emitting lasers 110. The system light 1001 may (in the first operational mode) comprise the luminescent material light 201. Especially, the luminescent material light 201 may comprise an emission band having a full width half maximum of at least 40 nm. A possible spectral power distribution is schematically depicted in FIG. 3b.

In embodiments, such as embodiments I and II of FIG. 3a, the luminescent material 200 may comprise a luminescent material of the type A₃B₅O₁₂:Ce³⁺. A may comprise one or more of Y, La, Gd, Tb and Lu. B may comprise one or more of Al, Ga, In and Sc. Alternatively or additionally, the luminescent material may comprise one or more other luminescent materials.

The luminescent material may be configured downstream of a first VCSEL or an optional second light source 120. In embodiments, different luminescent materials may be configured downstream of different VCSELs and/or optional second light sources 120. In specific embodiments, downstream of at least one, more especially downstream between of at least two different VCSEL no luminescent material is configured (i.e. the first laser light of such VCSELs may end up in the system light (in the operational mode)).

The terms “upstream” and “downstream” relate to an arrangement of items or features relative to the propagation of the light from a light generating means (here the especially the light source), wherein relative to a first position within a beam of light from the light generating means, a second position in the beam of light closer to the light generating means is “upstream”, and a third position within the beam of light further away from the light generating means is “downstream”.

Referring to FIG. 3a, embodiment III, the light generating system 1000 may further comprise a third light generating device 130 configured to generate third device light 131. The third light generating device 130 may comprise a laser. The third device light 131 has a third device light centroid wavelength (λ_{c3}) which may be at a fixed position (during the first operational mode). Especially, the n first vertical cavity surface emitting lasers 110 may be configured to generate (in the first operational mode of the light generating system 1000) first laser light 111 having time averaged centroid wavelength(s) (λ_{nac}). The third device light centroid wavelength (λ_{c3}) may differ from at least one of the time averaged centroid wavelength(s) (λ_{nac}) of the first laser light 111 of the n first vertical cavity surface emitting lasers 110, more especially of all of the time averaged centroid wavelengths (λ_{nac}) of the first laser light 111 of all of the n first vertical cavity surface emitting lasers 110. A possible spectral power distribution is schematically depicted in FIG. 3c.

In specific embodiments, the control system 300 may be configured to control the correlated color temperature of the system light 1001 (in the first operational mode) at a value selected from the range of 1800-6500 K. Especially, in embodiments the correlated color temperature of the system light 1001 may be at least controllable over a CCT control range of at least 500 K within the range of 1800-6500 K.

In embodiments, the control system 300 may be configured to control the color rendering index of the system light 1001 (in the first operational mode) at a value of at least 90.

Controlling the spectral power distribution of the system light 1001 (in the operational mode) may comprise individually controlling a duty cycle of first pules and a duty cycle of the second time periods.

Especially, n≥3.

In embodiments, the control system 300 may be configured to control the R9 value of the system light 1001 (in the first operational mode) at a value of at least 40, or even higher, such as at least 50. As can be derived from FIGS. 3b-3c, a luminescent material may be useful to increase R9. The R9 value may be controllable over a R9 control range of at least 30. Especially, the R9 control range at least partly overlaps with the range of at least 40. In embodiments, (in the first operational mode) the color rendering index of the system light 1001 may be at least 80.

In FIGS. 3b-3c, the spectral power distribution of a black body radiator (emission) at a specific temperature is indicated with the continuous line from left below to the upper right.

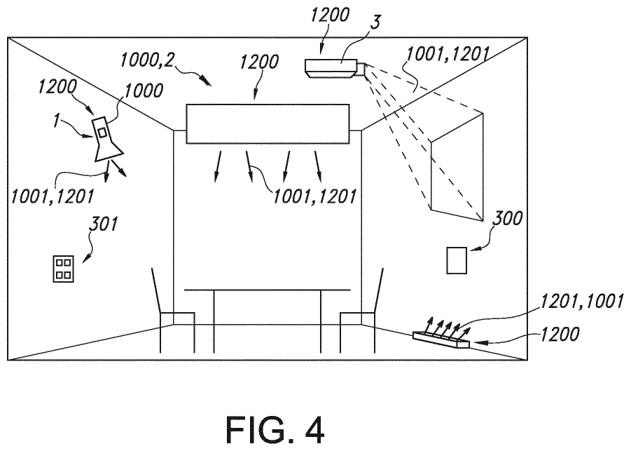

FIG. 4 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 4 also schematically depicts an embodiment of lamp 1 comprising the light generating system 1000. Reference 3 indicates a projector device or projector system, which may be used to project images, such as at a wall, which may also comprise the light generating system 1000. Hence, FIG. 4 schematically depicts embodiments of a lighting device 1200 selected from the group of a lamp 1, a luminaire 2, a projector device 3, a disinfection device, a photochemical reactor, and an optical wireless communication device, comprising the light generating system 1000 as described herein. In embodiments, such lighting device may be a lamp 1, a luminaire 2, a projector device 3, a disinfection device, or an optical wireless communication device. Lighting device light escaping from the lighting device 1200 is indicated with reference 1201. Lighting device light 1201 may essentially consist of system light 1001, and may in specific embodiments thus be system light 1001.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A light generating system comprising n first vertical cavity surface emitting lasers, a second light generating device and a control system, wherein n≥1, wherein the second light generating device is configured to generate second light generating device light and wherein each of the n first vertical cavity surface emitting lasers is configured to generate first laser light changing between at least two centroid wavelengths (λ_{nc,1}, λ_{nc,2}) having a wavelength difference of at least 10 nm, with a changing frequency of at least 50 Hz; wherein the control system is configured to control the n first vertical cavity surface emitting lasers such that system light is generated comprising the second light generating device light and the first laser light of at least one of the n first vertical cavity surface emitting lasers, and wherein the control system is configured to control a spectral power distribution of the system light, wherein the system light is white light having a correlated color temperature in a range from 1800 K to 8000 K and a color rendering index of at least 70.

2. The light generating system according to claim 1, wherein each of the n first vertical cavity surface emitting lasers is configured to generate first laser light changing between at least two centroid wavelengths (λ_{nc,1}, λ_{nc,2}) having a wavelength difference of at least 20 nm, wherein at least one of the n first vertical cavity surface emitting lasers is configured to generate first time periods of first laser light having a first centroid wavelength (λ_{nc,1}) and second time periods of first laser light having a second centroid wavelength (λ_{nc,2}), each with a time period frequency of at least 50 Hz; wherein the at least one of the n first vertical cavity surface emitting lasers is configured to provide the first laser light averaged over time as an emission band, wherein the first laser light has a time dependent centroid wavelength (λ_{nct}) varying over time between the first centroid wavelength (λ_{nc,1}) and the second centroid wavelength (λ_{nc,2}), wherein a spectral power distribution of the first laser light averaged over time is conformal to at least part of the spectral power distribution of the emission of a black body radiator at a specific correlated color temperature in the range of 1800-8000 K.

3. The light generating system according to claim 1, comprising at least two first vertical cavity surface emitting lasers configured to generate first laser light changing between the at least two centroid wavelengths (λ_{nc,1}, λ_{nc,2}) in at least two different wavelength ranges which wavelength ranges overlap less than 50%.

4. The light generating system according to claim 1, comprising at least three vertical cavity surface emitting lasers configured to generate first laser light having different time averaged centroid wavelengths (λ_{nac}) selected from wavelength ranges of the group of 440-495 nm, 495-570 nm, 570-590 nm, 590-620 nm, and 620-780 nm, wherein at least three time averaged centroid wavelengths (λ_{nac}) mutually differ at least 40 nm.

5. The light generating system according to claim 1, wherein the n first vertical cavity surface emitting lasers are configured to generate system light having radiant flux at at least four different wavelengths in the wavelength range of 380-780 nm, wherein a smallest and a largest wavelength where the n first vertical cavity surface emitting lasers provide intensity span a wavelength range of at least 110 nm; wherein averaged over time at least 50% of a radiant flux of the first laser light is at the at least 4 different wavelength ranges within the range of 380-780 nm.

6. The light generating system according to claim 1, wherein at least one of the n first vertical cavity surface emitting lasers is configured to generate first laser light wherein averaged over time at least 60% of a radiant flux of the first laser light is within at least 8 different non-overlapping wavelength ranges of at least 10 nm width within the range of 380-780 nm.

7. The light generating system according to claim 6, wherein all of the n first vertical cavity surface emitting lasers are configured to generate together first laser light wherein averaged over time at least 80% of a radiant flux of the first laser light is within at least 11 different non-overlapping wavelength ranges of at least 10 nm width within the range of 380-780 nm.

8. The light generating system according to claim 1, further comprising a luminescent material configured to convert at least part of the light of the second light generating device, wherein the system light comprises the luminescent material light, and wherein the luminescent material light comprises an emission band having a full width half maximum of at least 40 nm.

9. The light generating system according to claim 1, further comprising a luminescent material configured to convert at least part of the light of at least one of the n first vertical cavity surface emitting lasers, wherein the system light comprises the luminescent material light, and wherein the luminescent material light comprises an emission band having a full width half maximum of at least 40 nm.

10. The light generating system according to claim 9, wherein the luminescent material comprises a luminescent material of the type A₃B₅O₁₂:Ce, wherein A comprises one or more of Y, La, Gd, Tb and Lu, and wherein B comprises one or more of Al, Ga, In and Sc.

11. The light generating system according to claim 1, further comprising a third light generating device configured to generate third device light, wherein the third light generating device comprises a laser, wherein the third device light has a third device light centroid wavelength (λ_{c3}) which is at a fixed position, wherein the n first vertical cavity surface emitting lasers (110) are configured to generate first laser light having time averaged centroid wavelength(s) (λ_{nac}), wherein the third device light centroid wavelength (λ_{c3}) differs from at least one of the time averaged centroid wavelength(s) (λ_{nac}) of the first laser light of the n first vertical cavity surface emitting lasers.

12. The light generating system according to claim 1, wherein the control system is configured to control the correlated color temperature of the system light at a value selected from the range of 1800-6500 K; wherein the correlated color temperature of the system light is at least controllable over a CCT control range of at least 500 K within the range of 1800-6500 K.

13. The light generating system according to claim 1, wherein the control system is configured to control the color rendering index of the system light at a value of at least 90; wherein controlling the spectral power distribution of the system light comprises individually controlling a duty cycle of first pules and a duty cycle of the second time periods.

14. The light generating system according to claim 1, wherein n≥3, and wherein the control system is configured to control the R9 value of the system light at a value of at least 40; wherein the R9 value is controllable over a R9 control range of at least 30, wherein the R9 control range at least partly overlaps with the range of at least 40; and wherein the color rendering index of the system light is at least 80.

15. A lighting device selected from the group of a lamp, a luminaire, a projector device, a disinfection device, a photochemical reactor, and an optical wireless communication device, comprising the light generating system according to claim 1.
